(19) United States
(12) Patent Application Publication
(10) Pub. No.: US 2010/0194009 A1
(43) Pub. Date: Aug. 5, 2010

(54) Substrate holding platen with adjustable shims

(75) Inventors: Lionel Fullwood, St. George, UT (US); Greg Baxter, Palm Desert, CA (US); John H. Hart, Woodland Hills, CA (US); Raja D. Singh, Claremont, CA (US)

Correspondence Address: REED SMITH LLP, 101 Second Street, Suite 1800, SAN FRANCISCO, CA, 94105, US

(73) Assignee: WKK Distribution, Ltd.

(21) Appl. No.: 12/322,504

(22) Filed: Feb. 3, 2009

(51) Int. Cl. H01L 21/687

(52) U.S. Cl. 269/9; 269/903; 269/329

(57) ABSTRACT

A panel platen for holding substrates such as PCBs has an automatic shimming mechanism to provide shims for panels of varying sizes and/or thicknesses. A platen includes a top surface, and a plurality of adjustable shims located below the top surface and around an edge of the platen, wherein the adjustable shims can be raised and lowered to a desired height to compensate for different sizes or thicknesses of substrates. A platen may include a top surface, a plurality of adjustable height pads located around an edge of the top surface, and a motorized control mechanism located below the top surface and configured to raise and lower the plurality of adjustable height pads. A method of automatically shimming different sized substrates on a platen includes providing a plurality of motorized shims under a top surface of the platen, and raising and lowering the motorized shims based on a size or thickness of a substrate.

### BACKGROUND OF THE INVENTION

1. Field of the Invention

The present invention relates generally to a system and method for exposing photolithographic materials on various substrates to light energy, and more particularly, to an improved substrate holding platen having adjustable shims.

2. Description of the Related Art

Traditionally, Printed Circuit Boards (PCBs) require either a photosensitive polymer to define the circuit pattern during manufacture, or a protective coating over the defined circuit paths after the circuit pattern is defined so that shorting does not occur during component assembly. The material used in both instances is a robust photo polymerized organic layer. Ultraviolet light is used to “activate” the polymerization process used in PCB manufacturing. A single PCB or a multiple set of images on a substrate called a panel is placed in a UV light exposure system for a period from a few seconds to up to one minute. The various areas for exposure and non-exposure on the UV light are defined using photolithographic artwork on a polyester sheet or glass, and this artwork is then normally mounted on a plate of within the exposure machine. Ultraviolet light is also used in industrial processes to cure or harden various polymerizable materials used in other manufacturing processes including electronics, such as adhesive layers, cover coats, bonding materials, conformal coatings, and the like.

When processing substrates smaller than the maximum image area in the frame of the automated exposure apparatus, present art machines require the manual installation of shims that are the same thicknesses as the substrate being exposed. The function of the shim is to reduce glass breakage and bending toward the outside edges of the exposure frame, so that images are reproduced accurately. This manual shimming process introduces possible particulate contaminants, dramatically increases job set up times, and contributes to the likelihood of human error and the resultant product defects.

As an alternative to shimming and the problems associated therewith, many manufacturers prefer to manually align the photolithographic artwork to the substrate using an eye loop for registration verification. The package comprising the aligned artwork and substrate is then placed in a manual machine vacuum tray, the tray being then evacuated and the whole system exposed to ultraviolet energy for periods up to one minute.

The prior art systems have small vacuum pumps and small diameter vacuum tubing. In either automatic or manual exposure units, these prior systems take too long to completely evacuate a chamber to provide a flat, intimate contact between the photolithographic artwork and the panel for high speed operation. It would thus be desirable to have an adjustable shim system that could be used in either manual or automated exposure machines to significantly decrease the vacuum pull down time.

### SUMMARY OF THE INVENTION

In general, the present invention is a panel platen for holding substrates such as PCBs, which has an adjustable shimming mechanism to provide shims for panels of varying sizes and/or thicknesses. According to one embodiment, a platen comprises a top surface, and a plurality of adjustable shims located below the top surface and around an edge of the platen, wherein the adjustable shims can be raised and lowered to a desired height to compensate for different sizes and thicknesses of substrates.

The shims can comprise cylindrical pads raised and lowered through holes in the top surface of the platen. The platen can further comprise air holes in the top surface, and an air float supply system to provide air flow through the air holes in the top surface in order to support a substrate on an air film.

According to another embodiment a platen may comprise a top surface, a plurality of adjustable height pads located around an edge of the top surface, and a motorized control mechanism located below the top surface and configured to raise and lower the plurality of adjustable height pads.

A method of automatically shimming different sized substrates on a platen according to an embodiment of the present invention comprises providing a plurality of motorized shims under a top surface of the platen, and raising and lowering the motorized shims based on a size or thickness of a substrate.

### BRIEF DESCRIPTION OF THE DRAWINGS

The present invention will be readily understood by the following detailed description in conjunction with the accompanying drawings, wherein like reference numerals designate like structural elements, and in which:

FIG. 1 is a first view of one embodiment of a transport and exposure system according to the present invention;

FIG. 2 is a second view of the system of FIG. 1;

FIG. 3 illustrates a platen according to an embodiment of the present invention;

FIG. 4 illustrates the internal mechanics of the platen of FIG. 3;

FIG. 5 is a top view of the platen of FIG. 3; and

FIG. 6 is a top view of the platen of FIG. 3, with the shims lowered.

### DETAILED DESCRIPTION OF THE INVENTION

The following description is provided to enable any person skilled in the art to make and use the invention and sets forth the best modes contemplated by the inventor for carrying out the invention. Various modifications, however, will remain readily apparent to those skilled in the art. Any and all such modifications, equivalents and alternatives are intended to fall within the spirit and scope of the present invention.

In general, the present invention provides shims in a platen whose height can be automatically or manually adjusted. To obviate the need for the introduction of manual shims as discussed earlier, the system provides a unique exposure substrate platen that integrates an auto adjustable array of shims, providing for the automated exposure of different substrate sizes without the tedious (and sometimes disastrous) manual mounting of shims. Because of its unique design, the present shim system eliminates particulates from normal shim materials, and results in a higher overall process yield. This shimming mechanism can be completely computer controlled (via computer controller(s) 4 and/or 63), and allows an operator to set the shim height to match the thickness of a panel being processed, from about 0.2 mm up to 3 or 4 mm.

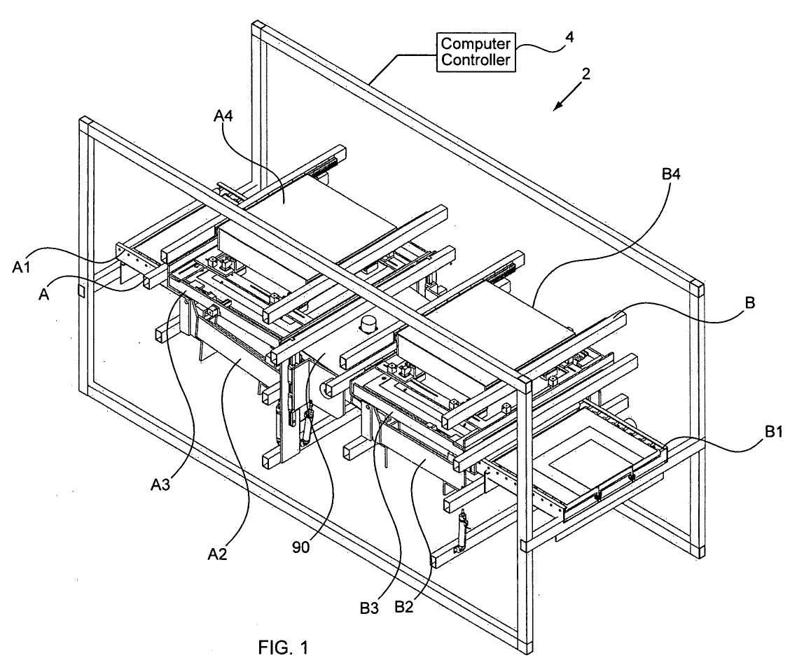

An automatic substrate transport system that incorporates a platen according to an embodiment of the present invention is illustrated in FIG. 1. The present invention will be described herein with respect to a specific system for processing PCB substrates. However, the teachings of the present invention can be applied to any substrates having photo-polymerizable material that need to be processed through a UV lamp exposure system. The present transport unit 2 can process PCB panels ranging in size from 356 mm×356 mm (14″×14″ or smaller) to 610 mm×720 mm (24″×30″). The present design, of course, can easily be modified to accommodate smaller or larger panels. The panel thickness capability ranges from a minimum of 0.2 mm (0.008″) to a maximum of 5 mm (0.200″). The entire system can be computer controlled (via computer controller 4).

The transport unit 2 receives a panel to the Infeed Roller Assembly A1 from a manufacturer's conveyance device (on the left, not shown), pre-aligns it and holds a panel (outline shown) until it is needed at the Side A Exposure area A. The panel is then driven forward by the rollers onto the Side A Panel Platen A2 where it is suspended on a film of air (supplied via an air float supply system 86). The panel is more precisely pre-aligned, secured in place by changing the air flow mode from float to vacuum (via panel hold vacuum supply 85), and then lifted up to the Artwork Alignment Module A3. Four CCD (or CMOS image sensor) cameras (not shown) with machine vision compare the positions of the artwork targets with the targets to be aligned located on the PCB. The alignment is corrected to the desired tolerance, full chamber vacuum is applied and the UV exposure takes place by activating the UV lamp module A4.

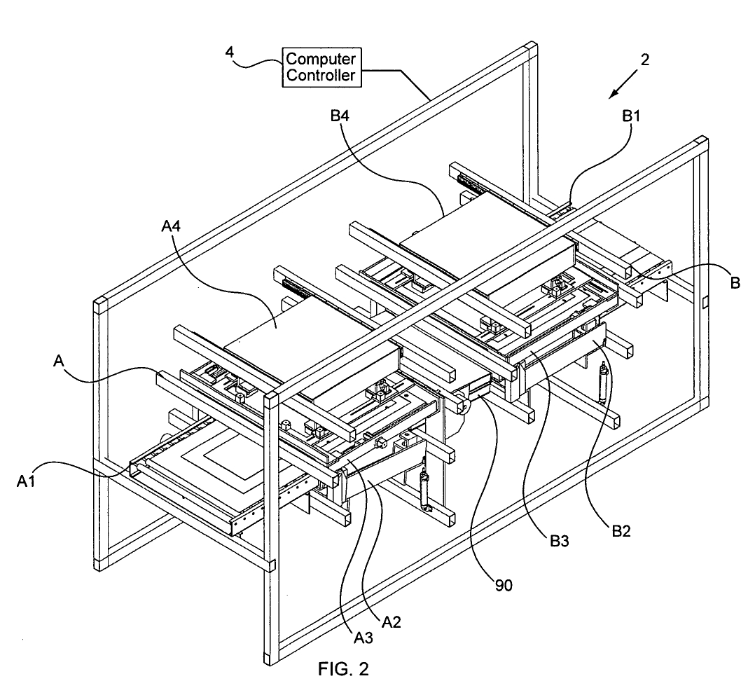

The Side A Panel Platen A2 is then lowered, the air flow is changed from vacuum to float, and the panel is again transported on a film of air into the Panel Flipping Module 80 where it is rotated 180 degrees, still supported on a film of air, and then subsequently loaded onto the Side B Panel Platen B2. The opposite side of the panel (Side B) is then aligned and exposed in the same manner as Side A. The panel is then conveyed to the Outfeed Roller Assembly B1 where it is driven out of the transport system 2 for the next process. FIG. 2 illustrates an alternate view of the system of FIG. 1.

### Side A and Side B Panel Platens

The Panel Platens A2, B2 are the hearts of each Exposure Station A, B. Each platen provide a combination of material transport, more precise panel pre-alignment, PCB holding for alignment and exposure, and a chamber vacuum system to place the panel in intimate contact with the artwork for UV exposure after alignment.

Tilt, Float, Pre-Align and Secure Panel for Exposure

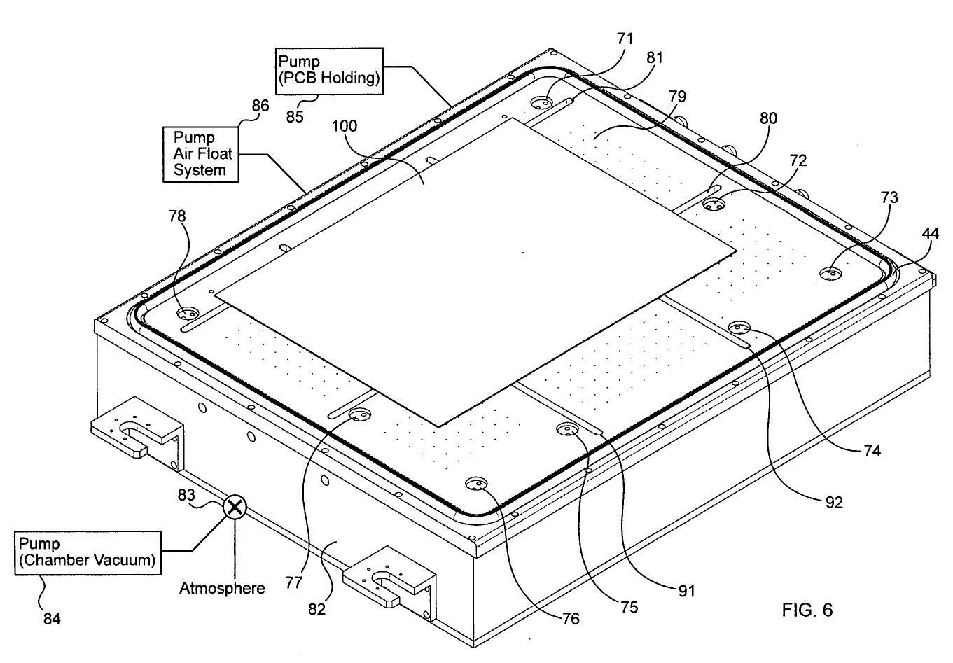

Each platen A2, B2 is tilted about 5 degrees downward to provide gravity movement to receive a PCB substrate. The panel platen A2, B2 has smooth, hardened surfaces plus an air bearing design that enables the panel to float with very low friction while moving downward by gravity. The air float system is similar to the concept used in an “air hockey” game, for example. The air float system includes an air pump (86; FIG. 6) to provide the necessary air flow to the platens and/or flipper module. Additional air pump systems may be provided, if desired. In a preferred embodiment, the platens A2, B2 are made from Teflon™ impregnated hard anodized aluminum to further prevent any material from sticking. This design prevents the panel's resist surfaces from being scuffed during transport. It also eliminates the need for pick-up and transport arms, reduces complexity and the air cushion provides additional cooling to the panel during transport and UV exposure.

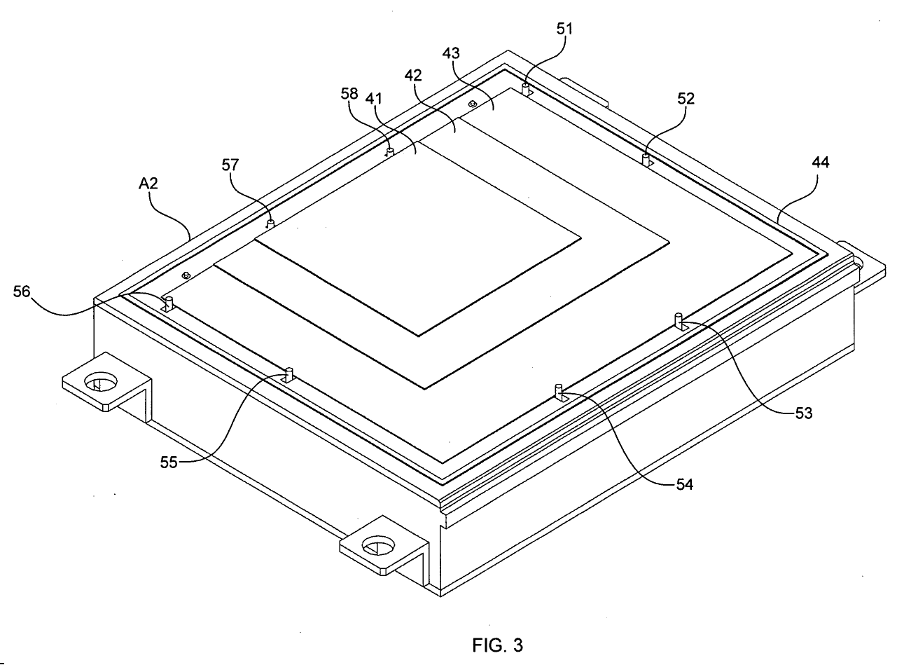

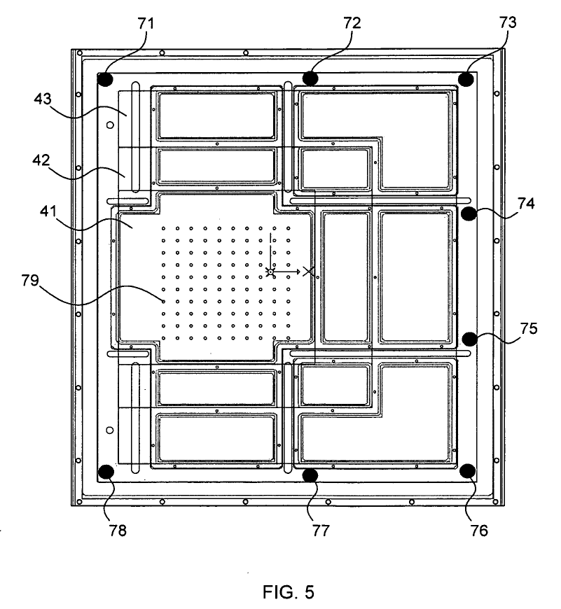

When a platen A2 is ready to accept a panel for processing, an Infeed Roller A1 propels the pre-aligned panel forward onto the floating downward-angled surface. As illustrated in FIG. 3, the platen A2 more precisely pre-aligns the panel to its center and leading edge, which for Side A is on the left, using motor driven snubbers 51-58. Once the panel is in proper position, the air bearing surface converts to a unique vacuum chuck (described below) to secure the PCB firmly in place and then the snubbers 51-58 completely retract. As shown in FIG. 3, the platen is configured to handle PCB panels of different sizes 41, 42, 43. As further illustrated in FIG. 5, the vacuum chuck has several zones to securely hold small to large panel sizes effectively. In other words, a separate panel holding vacuum can be applied in different zones to hold different sized panels, if required. The platen also has an inflatable chamber vacuum seal 44 around the perimeter to enable chamber vacuum exposures for a variety of panel thicknesses.

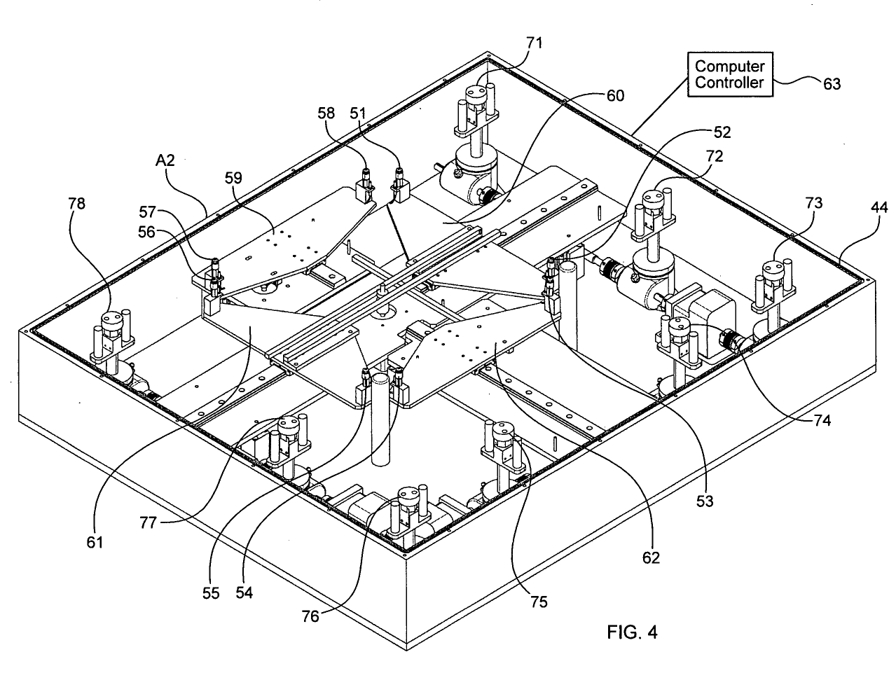

The internal mechanics of the platen A2 is shown in further detail in FIG. 4. The snubbers 51-58 are controlled by motorized plates 59-61, which slide along tracks as shown. In addition, automatic shims 71-78 are placed around the edge of the platen A2. In a preferred embodiment, the shims 71-78 are constructed as jack screws which can be raised and lowered, as described below.

FIG. 5 illustrates a top view of the platen showing the air holes 79 which allow forced air from an air supply system (not shown) to provide the air film to float the panel. It can be seen that the air holes 79 are centered to support panels which are sized for any of the three sizes 41, 42, 43. During processing, the different panel handling zones can pull a vacuum separate from the chamber vacuum. Also, it can be seen that open grooves on the top face are provided to allow the snubbers 51-58 to move back and forth, depending on the size of the panel. The air holes are used to float the panel during the handling process, and are used as a vacuum hold during the exposure process.

As discussed above, if a panel is smaller than the glass plate in the exposure module, when a vacuum is pulled to adhere the panel to the glass, the glass could break, since the edges of the glass have no support. In prior art systems, a manual shim (i.e. a template) would be created to fill in the gaps around a smaller panel. However, such a solution requires significant manual set-time up. It can also generate contaminants in the form of dust, debris, or adhesive residue.

Accordingly, each platen A2, B2 contains a uniquely designed feature that eliminates the need for manual panel shimming to prevent glass breakage during chamber vacuum exposures. FIGS. 4 and 5 depict the strategically placed motorized spacers [71-78] that automatically support large gaps between the tempered glass plate in the exposure module and the platen A2, B2 due to smaller panel sizes. The shims 71-78 protrude to approximately the same distance as the panel thickness (or more or less as desired), and enable uniform vacuum flow for quick draw down and quicker exposure cycles. This feature significantly reduces set-up times, particle defects because of tape used to hold down the inserted shims in the exposure area, and the potential for operator errors during the placement of shims. It also protects the expensive glass plate that holds the film artworks.

In operation, the shims 71-78 are raised and/or lowered as needed, depending on the size and/or thickness of the panel material. The settings can be computer controlled (via computer controller 4 and/or 63) based on an operator's input of the size of the panel being processed. The shims can also be manually adjusted, if desired. The shims 71-78 can even be set slightly higher or lower than the panel thickness, if desired.

Also illustrated in FIG. 4 is further detail about how the centering snubbers 59-62 operate. The positioning of the snubbers is computer controlled, based on the size of the panels being processed. The shims could also be manually adjusted. The snubbers along the “leading edge” (upper left) additionally push the exposed panel along the sloped floating surface into the Panel Flipping Module 80. The Side B Platen B2 is identical in construction to the Side A platen A2 except the leading edge for the panel faces right.

Panel Chamber Vacuum System

As described above, a vacuum chamber is used to provide a flat, intimate contact between the photolithographic artwork to the PCB panel. In prior systems, production slow-downs are typically encountered during imaging caused by the inherent delays programmed by the operator to assure that the Chamber Vacuum has reached sufficient contact with the PCB to guarantee acceptable exposures. Most prior systems pull an initial vacuum level quickly enough, but the process of evacuating the small spaces between the PCB and artworks for acceptable yields takes considerable time. This occurs because, once initial contact is attained, there is an insufficient flow orifice to the vacuum pump remaining to quickly accomplish the task. In other words, the vacuum flow orifice(s) are so small, when the PCB panel is brought close to the artwork, the small orifices are further blocked, reducing the effective flow rate.

The present system therefore has a specially designed vacuum system and method that utilizes the region under the platen vacuum chuck as a high flow plenum to pull the required vacuum much more quickly.

In further detail, as illustrated in FIG. 6, each platen A2, B2 incorporates a high flow vacuum pump 84 that draws vacuum with significantly higher flow rates compared to conventional systems plus large flow paths to speed up the vacuum draw and release steps. Specifically, the pumps for chamber vacuum 84 and panel holding 85 are external to the platen and the hoses are connected to the bottom of the platen.

After a PCB 100 is centered, it is securely held in place by a perforated vacuum plenum (supplied by pump 85) via perforated holes 79 in top surface of the platen (the air float supply system 86 is de-activated, and the panel hold vacuum supply 85 is activated). If desired, the holding panel holding vacuum may comprise a plurality of different zones, to accommodate different sized panels. The auto shims 71-78 are moved into a position level with the top surface of the PCB 100.

An inflatable seal 44 raises to the glass that holds the artwork (not shown), and seals the platen against the glass. The enclosed/sealed area 82 inside the platen is vented to atmosphere by a switchable large orifice valve 83 until a chamber vacuum is required, and then the valve 83 is shuttled to seal the plenum (area) below the platen plate. The large orifice valve 83 then connects the plenum to the high flow vacuum pump 84. The high flow pump 84 pulls a vacuum down through the centering slots (i.e. slots 80, 81, 91, 92 used by the snubbers 51-56) and the area around the shims in the platen plate for a quick and uniform drawdown. Separate valves could be used for venting and pulling vacuum, if desired. The large orifice valve preferably has ports at least 1 (25 mm) to 2 (50 mm) inches in diameter, and in a preferred embodiment, the valve has 1½ inch (38 mm) ports. In one embodiment, the high flow pump 84 is capable of pulling 100-150 cfm of air from the plenum area under the platen surface. Note that even when the PCB panel and the artwork glass are brought together, there are still large areas (slots, holes) to pull vacuum, in contrast to prior art systems.

Once the PCB is exposed, the enclosed/sealed area 82 is again vented to atmosphere. Since the platen surface contains rather large slots 80, 81, 91, 92 and other openings, the vacuum is quickly removed, providing for faster system operation. After the exposure is complete, the panel hold vacuum supply 85 is de-activated, and the air float supply system 86 is re-activated in the platen, to re-float the substrate.

Those skilled in the art will appreciate that various adaptations and modifications of the just-described preferred embodiments can be configured without departing from the scope and spirit of the invention. Therefore, it is to be understood that, within the scope of the appended claims, the invention may be practiced other than as specifically described herein.

What is claimed is:

1. A platen comprising:
a top surface; and
a plurality of adjustable shims located below the top surface and around an edge of the platen;
wherein the adjustable shims can be raised and lowered to a desired height to compensate for different sizes or thicknesses of substrates.

2. The platen of claim 1, wherein the shims comprise cylindrical pads raised and lowered through holes in the top surface of the platen.

3. The platen of claim 2, further comprising air holes in the top surface.

4. The platen of claim 3, further comprising an air film system to provide air flow through the air holes in the top surface in order to support a substrate on an air film.

5. The platen of claim 4, further comprising at least one stop and at least two motorized snubbers to align a substrate on the platen.

6. A platen comprising:
a top surface;
a plurality of adjustable height pads located around an edge of the top surface; and
a motorized control mechanism located below the top surface and configured to raise and lower the plurality of adjustable height pads.

7. A method of automatically shimming different sized substrates on a platen; the method comprising:
providing a plurality of motorized shims under a top surface of the platen; and
raising and lowering the motorized shims based on a size or thickness of a substrate.
